(19) United States
(12) Patent Application Publication
(10) Pub. No.: US 2024/0155921 A1
(43) Pub. Date: May 9, 2024

(54) DISPLAY DEVICE AND METHOD FOR MANUFACTURING THE SAME

(71) Applicant: Samsung Display Co., LTD., Yongin-si (KR)

(72) Inventor: SEONG-SIK PARK, Yongin-si (KR)

(21) Appl. No.: 18/387,823

(22) Filed: Nov. 7, 2023

(30) Foreign Application Priority Data
Nov. 9, 2022 (KR) 10-2022-0148462

(51) Int. Cl. H10K 59/80; H10K 59/12; H10K 59/40

(52) U.S. Cl. CPC H10K 59/873; H10K 59/1201; H10K 59/40; H10K 2102/311

(57) ABSTRACT

A display device includes: a display panel including a display area and a peripheral area adjacent to the display area, and including an upper surface having a first concave-convex pattern protruding or recessed in a thickness direction, a polarization member disposed on the display panel, overlapping the display area and a portion of the peripheral area, and including an upper surface having a second concave-convex pattern protruding or recessed the thickness direction, a cover window disposed on the polarization member, and a light blocking layer disposed on a lower surface of the cover window and overlapping a portion of the peripheral area.

This application claims priority to Korean Patent Application No. 10-2022-0148462, filed on Nov. 9, 2022, and all the benefits accruing therefrom under 35 U.S.C. § 119, the content of which in its entirety is herein incorporated by reference.

### BACKGROUND

### 1. Field

Embodiments provide generally to a display device and a method for manufacturing the display device. More particularly, embodiments relate to a display device that provides visual information and a method of manufacturing the display device.

### 2. Description of the Related Art

With the development of information technology, the importance of a display device, which is a connection medium between a user and information, has been highlighted. For example, the use of a display device such as a liquid crystal display device (“LCD”), an organic light emitting display device (“OLED”), a plasma display device (“PDP”), a quantum dot display device, or the like is increasing.

Recently, a display device using a substrate including a flexible material is widely used to reduce a dead space of the display device. The dead space of the display device may refer to a non-display area in which an image is not displayed located around a display area in which an image is displayed.

### SUMMARY

Embodiments provide a display device with reduced dead space.

Embodiments provide a method for manufacturing the display device.

A display device according to embodiments of the present disclosure includes a display panel including a display area and a peripheral area adjacent to the display area, and including an upper surface having a first concave-convex pattern protruding in a thickness direction, a polarization member disposed on the display panel, overlapping the display area and a portion of the peripheral area, and including an upper surface having a second concave-convex pattern protruding the thickness direction, a cover window disposed on the polarization member, and a light blocking layer disposed on a lower surface of the cover window and overlapping a portion of the peripheral area.

In an embodiment, each of the first concave-convex pattern and the second concave-convex pattern may overlap the portion of the peripheral area.

In an embodiment, the light blocking layer may overlap a portion of the polarization member.

In an embodiment, the light blocking layer may at least partially overlap each of the first concave-convex pattern and the second concave-convex pattern in the thickness direction.

In an embodiment, the display panel may include a transistor disposed in the display area on a substrate, a light emitting element disposed on the transistor and electrically connected to the transistor, an encapsulation layer disposed on the light emitting element, and a touch layer disposed on the encapsulation layer.

In an embodiment, an upper surface of the touch layer may have the first concave-convex pattern.

In an embodiment, the display panel may further include a pad area and a bending area located between the peripheral area and the pad area in a plan view.

In an embodiment, the display device may further include a bending protection layer disposed on the display panel and overlapping a portion of the peripheral area and the bending area.

In an embodiment, each of the first concave-convex pattern and the second concave-convex pattern may overlap a portion of the peripheral area adjacent to the bending protection layer.

In an embodiment, the bending protection layer may directly contact the polarization member in the peripheral area.

In an embodiment, the bending protection layer may be spaced apart from the polarization member in the peripheral area.

A method for manufacturing a display device according to embodiments of the present disclosure, the method includes preparing a display panel including a display area and a peripheral area adjacent to the display area, forming a first concave-convex pattern protruding or recessed in a thickness direction on an upper surface of the display panel, attaching a polarization member to the display panel to overlap the display area and a portion of the peripheral area, forming a second concave-convex pattern protruding or recessed in the thickness direction on an upper surface of the polarization member, providing a light blocking layer on a lower surface of a cover window, and attaching the cover window and the light blocking layer to the polarization member in a way such that the light blocking layer overlaps a portion of the peripheral area.

In an embodiment, the method may further include providing a panel protection film on the display panel before the forming the first concave-convex pattern. In such an embodiment, the attaching the polarization member on the display panel may include providing a polarization protection film on the polarization member and attaching the polarization member, on which the polarization protection film is provided, to the display panel.

In an embodiment, the method may further include removing the panel protection film after the forming the first concave-convex pattern.

In an embodiment, the method may further include removing the polarization protection film after the forming the second concave-convex pattern.

In an embodiment, the forming the first concave-convex pattern may include radiating a laser beam or applying plasma to a portion of an upper surface of the display panel which does not overlap the panel protection film and overlaps a portion of the peripheral area.

In an embodiment, the forming the second concave-convex pattern may include radiating a laser beam or applying plasma to a portion of an upper surface of the polarization member which does not overlap the polarization protection film and overlaps a portion of the peripheral area.

In an embodiment, the attaching the polarization member on the display panel may include providing a preliminary polarization protection film entirely on the polarization member, attaching the polarization member, on which the preliminary polarization protection film is provided, to the display panel, and forming a polarization protection film overlapping the display area and a portion of the peripheral area by cutting the preliminary polarization protection film using a laser beam.

In an embodiment, the attaching the polarization member on the display panel may include providing a polarization protection film having a size determined to overlap the display area and a portion of the peripheral area on the polarization member and attaching the polarization member, on which the polarization protection film is provided, to the display panel.

In an embodiment, the method may further include removing air bubbles formed between the polarization member and the cover window after the attaching the cover window and the light blocking layer to the polarization member. In such an embodiment, the air bubbles may be removed by an auto clave.

In a display device according to embodiments of the invention, an upper surface of a display panel may have a first concave-convex pattern protruding or recessed in a thickness direction, and an upper surface of a polarization member disposed on the display panel may have a second concave-convex pattern protruding or recessed in the thickness direction.

Accordingly, in such embodiments, interfacial adhesion between the display panel and the polarization member may be enhanced, and interfacial adhesion between the polarization member and an upper adhesive layer may be enhanced. In such embodiments, shrinkage due to moisture penetrating into an inside of the polarization member may be improved after a reliability evaluation is performed on the polarization member in a high-temperature and high-humidity environment. In such embodiments, when a bending protection layer is formed on the display panel, a step may not occur between the polarization member and the bending protection layer, and air bubbles may not be generated due to a step at an end of the upper adhesive layer adjacent to the bending protection layer. Accordingly, in such embodiment, a dead space of the display device may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a block diagram illustrating an external device electrically connected to the display device of FIG. 1.

FIG. 3 is a cross-sectional view taken along line I-I′ of FIG. 1.

FIG. 4 is a cross-sectional view illustrating a bent shape of the display device of FIG. 3.

FIG. 5 is an enlarged cross-sectional view of area A of FIG. 3.

FIG. 6 is an enlarged cross-sectional view of an example of area B of FIG. 3.

FIG. 7 is an enlarged cross-sectional view of another example of area B of FIG. 3.

FIG. 8 is an enlarged cross-sectional view of area C of FIG. 6.

FIGS. 9 to 23 are cross-sectional views showing processes of an embodiment of a method for manufacturing the display device of FIGS. 3 to 8.

FIG. 24 is a block diagram illustrating an embodiment of an electronic device including the display device of FIG. 1.

FIG. 25 is a view illustrating an embodiment in which the electronic device of FIG. 24 is implemented as a television.

FIG. 26 is a view illustrating an embodiment in which the electronic device of FIG. 24 is implemented as a smart phone.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms.

These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device according to embodiments of the present disclosure will be described in detail with reference to the accompanying drawings. The same reference numerals are used for the same components in the drawings, and any repetitive detailed descriptions of the same components will be omitted or simplified.

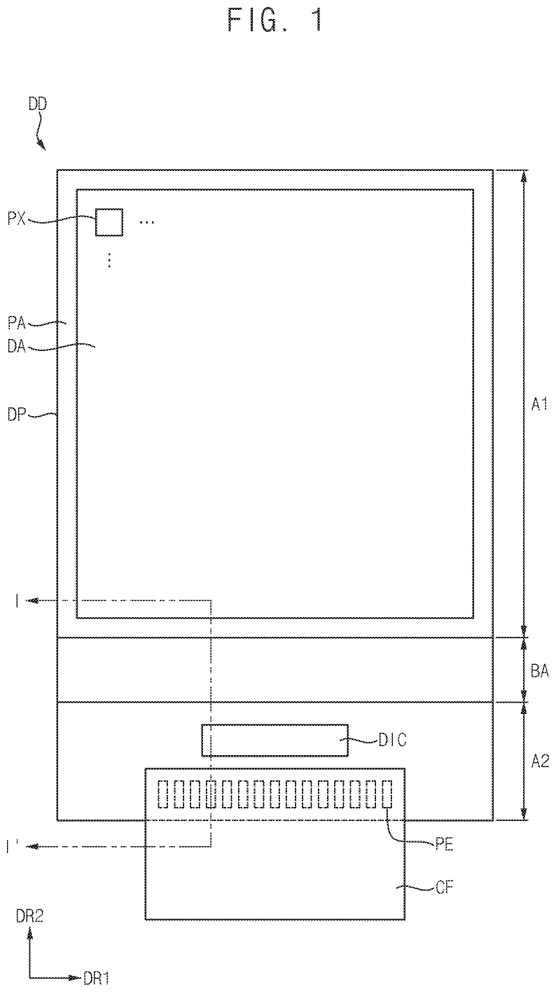

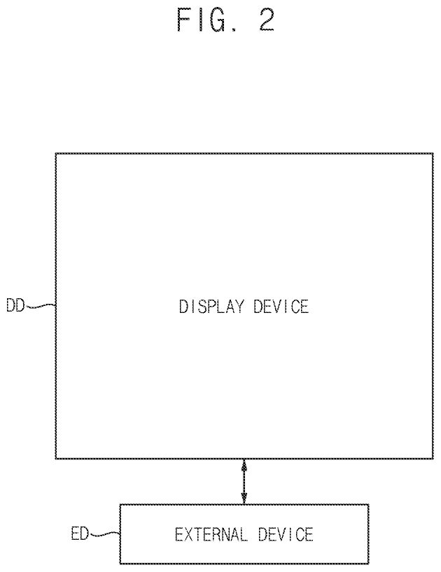

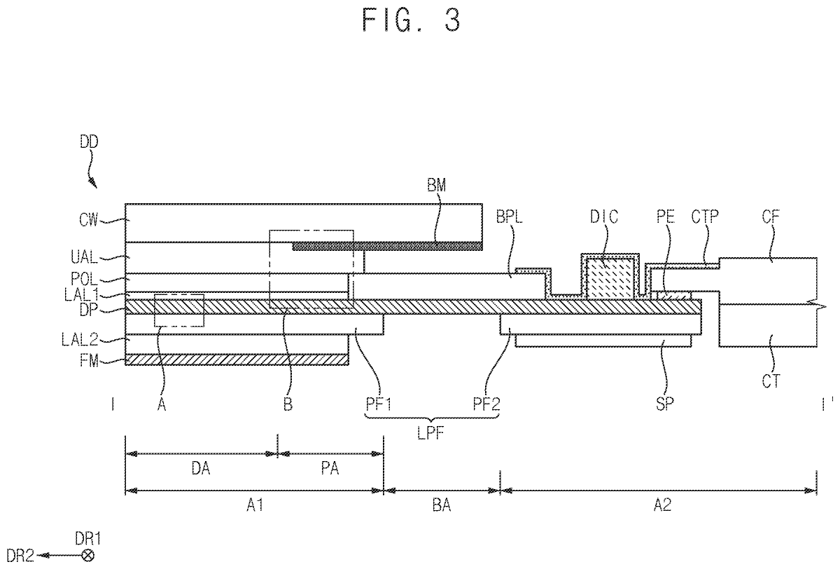

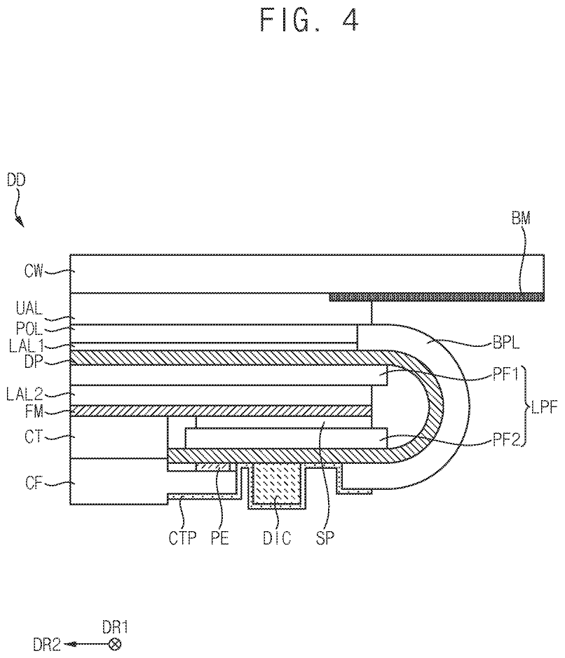

FIG. 1 is a plan view illustrating a display device according to an embodiment of the present disclosure. FIG. 2 is a block diagram illustrating an external device electrically connected to the display device of FIG. 1. Particularly, a display device DD illustrated in FIG. 1 is in a state before a display panel (e.g., a display panel DP of FIGS. 3 and 4) is bent.

Referring to FIGS. 1 and 2, the display device DD according to an embodiment may include the display panel DP, a driving integrated circuit DIC, pad electrodes PE, and a connection film CF.

In an embodiment, as shown in FIG. 1, the display device DD may have a rectangular planar shape. However, the present disclosure is not limited thereto, and the display device DD may have various planar shapes.

In an embodiment, the display panel DP may include a first area A1, a bending area BA, and a second area A2. In such an embodiment, the first area A1 may include the display area DA and the peripheral area PA.

The display area DA may be defined as an area capable of displaying an image by generating light or adjusting transmittance of light provided from an external light source. The peripheral area PA may be defined as an area not displaying an image. In addition, the peripheral area PA may surround at least a portion of the display area DA. In an embodiment, for example, the peripheral area PA may entirely surround the display area DA.

The second area A2 may be spaced apart from one side of the display area DA in a direction opposite to a second direction DR2 parallel to an upper surface of the display panel DP. The second area A2 may be defined as a pad area. The bending area BA may be located between the display area DA and the second area A2 in a plan view.

A plurality of pixel structures PX may be disposed in the display area DA. Each of the plurality of pixel structures PX may emit light. As each of the plurality of pixel structures PX emits light, the display area DA may display an image. In an embodiment, for example, the plurality of pixel structures PX may be arranged in a matrix form along a first direction DR1 and the second direction DR2 crossing the first direction DR1.

Lines (not shown) connected to the pixel structures PX may be further disposed in the display area DA. In an embodiment, for example, the lines may include a data signal line, a gate signal line, and a power line.

A driver for driving the plurality of pixel structures PX may be disposed in the peripheral area PA. In an embodiment, for example, the driver may include a data driver, a gate driver, a light emitting driver, a power voltage generator, a timing controller, or the like. The plurality of pixel structures PX may emit light based on signals transmitted from the drivers.

The driving integrated circuit DIC may be disposed in the second area A2 on the display panel DP. The driving integrated circuit DIC may convert a digital data signal among driving signals into an analog data signal and provide the converted analog data signal to the plurality of pixel structures PX. In an embodiment, for example, the driving integrated circuit DIC may be a data driver.

The pad electrodes PE may be disposed in the second area A2 on the display panel DP. The pad electrodes PE may be spaced apart from each other in the first direction DR1. Here, the first direction DR1 may be a direction substantially parallel to the upper surface of the display panel DP. Some of the pad electrodes PE may be connected to the driving integrated circuit DIC through a line, and the rest of the pad electrodes PE may be connected to the plurality of pixel structures PX through a line. Each of the pad electrodes PE may include a metal, an alloy, a metal nitride, a conductive metal oxide, a transparent conductive material, or the like. These may be used alone or in combination with each other.

One end of the connection film CF may be electrically connected to the pad electrodes PE and another end of the connection film CF may be electrically connected to the external device ED. That is, driving signal, driving voltage, or the like generated from the external device ED may be provided to the driving integrated circuit DIC and the plurality of pixel structures PX through the connection film CF and the pad electrodes PE. In an embodiment, for example, the connection film CF may include a flexible printed circuit board (“FPCB”), a printed circuit board (“PCB”), a flexible flat cable (“FFC”), or the like.

In an embodiment, as illustrated in FIG. 2, the external device ED may be electrically connected to the display device DD. In an embodiment, for example, the external device ED may be electrically connected to the display device DD through the connection film CF. The external device ED may generate the driving signal, the driving voltage, or the like to display an image on the display device DD.

In this specification, a plane may be defined as the first direction DR1 and the second direction DR2 crossing the first direction DR1. For example, the first direction DR1 may be perpendicular to the second direction DR2.

Hereinafter, components included in an embodiment of the display device DD will be described in detail.

FIG. 3 is a cross-sectional view taken along line I-I′ of FIG. 1. FIG. 4 is a cross-sectional view illustrating a bent shape of the display device of FIG. 3. Particularly, the display device DD illustrated in FIG. 3 is in a state before the display panel DP is bent, and the display device DD illustrated in FIG. 4 is in a state where the display panel DP is bent. In the display device DD, a portion of the display panel DP corresponding to the bending area BA may be provided in the bent state.

Referring to FIGS. 3 and 4, the display device DD according to an embodiment of the present disclosure may include the display panel DP, the pad electrode PE, a lower protective film LPF, a first lower adhesive layer LAL1, a second lower adhesive layer LAL2, a spacer SP, a functional member FM, a polarization member POL, a bending protection layer BPL, an upper adhesive layer UAL, a cover window CW, a light blocking layer BM, the driving integrated circuit DIC, a cover tape CT, the connection film CF, and a conductive tape CTP. In such an embodiment, the lower protective film LPF may include a first protective film PF1 and a second protective film PF2. Hereinafter, any repetitive detailed descriptions of the same or like elements as those of the display device DD described above with reference to FIG. 1 will be omitted.

The lower protective film LPF may be disposed on a lower surface of the display panel DP. In an embodiment, the first protective film PF1 may be disposed in the first area A1 on the lower surface of the display panel DP, and the second protective film PF2 may be in the second area A2 on the lower surface of the display panel DP. In such an embodiment, the lower protective film LPF may not be disposed in the bending area BA. The lower protective film LPF may protect the lower surface of the display panel DP.

The lower protective film LPF may include an inorganic material and/or an organic material. In an embodiment, for example, the lower protective film LPF may include an organic material such as photoresist, polyacrylic resin, polyimide resin, polyamide resin, siloxane resin, acrylic resin, epoxy resin, or the like. These may be used alone or in combination with each other.

An adhesive layer (not shown) may be disposed between the display panel DP and the lower protective film LPF. The adhesive layer may attach the lower protective film LPF to the lower surface of the display panel DP. A portion of the adhesive layer may overlap the bending area BA.

The second lower adhesive layer LAL2 may be disposed on a lower surface of the first protective film PF1. The second lower adhesive layer LAL2 may attach the functional member FM to the lower surface of the first protective film PF1. In an embodiment, for example, the second lower adhesive layer LAL2 may include optical clear adhesive (“OCA”), pressure sensitive adhesive (“PSA”), optical clear resin (“OCR”), or the like. These may be used alone or in combination with each other.

The functional member FM may be disposed on a lower surface of the second lower adhesive layer LAL2. In an embodiment, for example, the functional member FM may include a digitizer, a heat dissipation plate, or the like. The digitizer may be a device that converts coordinates of the input unit into digital data when an input unit such as a pen is into contact with the cover window CW. The digitizer may operate using an electromagnetic resonance method. In addition, the heat dissipation plate may dissipate heat transmitted to the lower surface of the display panel DP. The heat dissipation plate may include a material having high thermal conductivity. In an embodiment, for example, the heat dissipation plate may include graphite. Alternatively, the heat dissipation plate may include aluminum (Al), an alloy containing aluminum, copper (Cu), an alloy containing copper, silver (Ag), an alloy containing silver, or the like. These may be used alone or in combination with each other.

The spacer SP may be disposed on a lower surface of the second protective film PF2. In an embodiment, as shown in FIG. 4, the spacer SP may compensate for a step (i.e., a stepped structure or portion). Alternatively, the spacer SP may include an adhesive material, and the spacer SP may be fixed to a lower surface of the functional member FM. In an embodiment, for example, the spacer SP may include an organic insulating material such as photoresist, polyacrylic resin, polyimide-based resin, polyamide-based resin, siloxane-based resin, acrylic resin, epoxy-based resin, or the like. These may be used alone or in combination with each other.

The polarization member POL may be disposed in the first area A1 on the display panel DP. In an embodiment, the polarization member POL may overlap the display area DA and a portion of the peripheral area PA. The polarization member POL may block (or prevent a reflection of) external light incident on the display panel DP from the outside.

The first lower adhesive layer LAL1 may be disposed between the polarization member POL and the display panel DP. The first lower adhesive layer LAL1 may overlap display area DA and a portion of the peripheral area PA. The first lower adhesive layer LAL1 may attach the polarization member POL to the upper surface of the display panel DP. In an embodiment, for example, the first lower adhesive layer LAL1 may include OCA, OCR, PSA, or the like. These may be used alone or in combination with each other.

The bending protection layer BPL may be disposed on the display panel DP. The bending protection layer BPL may overlap a portion of the peripheral area PA, a portion of the bending area BA, and a portion of the second area A2. The bending protection layer BPL may control a neutral plane of the display device DD in the bending area BA.

The bending protection layer BPL may include a photocurable resin and/or a thermosetting resin. In an embodiment, for example, the bending protection layer BPL may include an epoxy resin, an amino resin, a phenol resin, a urea resin, a melamine resin, an unsaturated polyester resin, polyurethane resin, polyimide resin, or the like. These may be used alone or in combination with each other.

The upper adhesive layer UAL may be disposed on the polarization member POL and the bending protection layer BPL. The upper adhesive layer UAL may be disposed on a portion of the bending protection layer BPL and the polarization member POL. The upper adhesive layer UAL may attach the cover window CW and the light blocking layer BM to the polarization member POL and the bending protection layer BPL. In an embodiment, for example, the upper adhesive layer UAL may include OCA, OCR, PSA, or the like. These may be used alone or in combination with each other.

The cover window CW may be disposed on the upper adhesive layer UAL. The cover window CW may protect the polarization member POL, the bending protection layer BPL, and the display panel DP. The cover window CW may include reinforced glass or reinforced plastic. Alternatively, the cover window CW may be formed of (or defined by) a single layer or may have a structure in which a plurality of functional layers are stacked, i.e., a multi-layered structure.

The light blocking layer BM may be disposed on a lower surface of the cover window CW. The light blocking layer BM may overlap a portion of the peripheral area PA and the bending area BA. That is, the light blocking layer BM may not be disposed in the display area DA. In an embodiment, for example, the light blocking layer BM may include an inorganic material and/or an organic material containing black pigment, black dye, carbon black, or the like. These may be used alone or in combination with each other.

The conductive tape CT may be disposed on a lower surface of the connection film CF. In an embodiment, as illustrated in FIG. 4, when a portion of the display panel DP overlapping the bending area BA is bent, the conductive tape CT may compensate for a step. Alternatively, the conductive tape CT may include an adhesive material, and the conductive tape CT may be fixed to the lower surface of the functional member FM. In an embodiment, for example, the conductive tape CT may include an anisotropic conductive film (ACF) or the like.

The cover tape CTP may be disposed in the second area A2 on the driving integrated circuit DIC. The cover tape CTP may be disposed on a portion of the bending protection layer BPL and a portion of the connection film CF. In the second area A2 adjacent to the bending area BA, one end of the cover tape CTP may overlap the bending protection layer BPL, and another end of the cover tape CTP may overlap the connection film CF. That is, the cover tape CTP may cover the driving integrated circuit DIC. The cover tape CTP may shield electromagnetic wave emitted from the driving integrated circuit DIC in the second area A2. Accordingly, electromagnetic interference (“EMI”) caused by the electromagnetic wave and an external device may be reduced. In an embodiment, for example, the cover tape CTP may include a synthetic resin such as PET or the like.

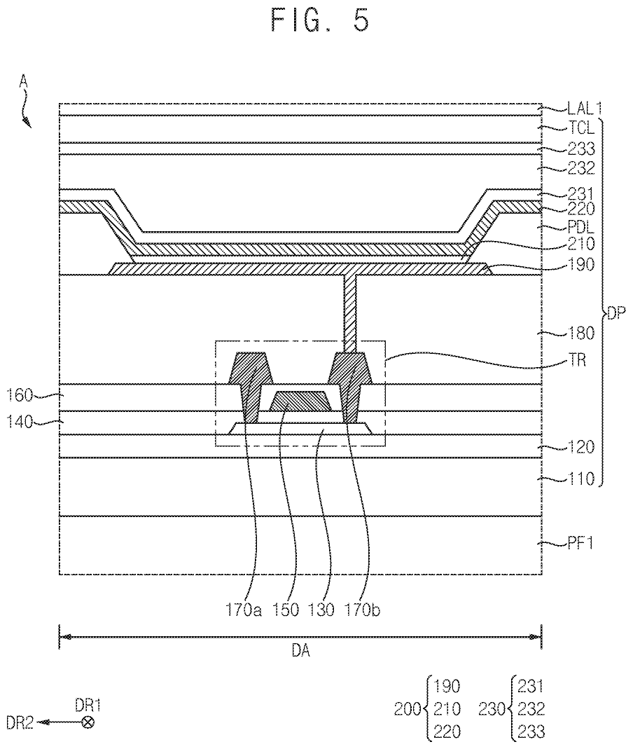

FIG. 5 is an enlarged cross-sectional view of area A of FIG. 3. Particularly, FIG. 5 is an enlarged cross-sectional view of a portion of the display area DA of the display panel DP illustrated in FIG. 3.

Referring to FIG. 5, an embodiment of the display panel DP may include a substrate 110, a buffer layer 120, a transistor TR, a gate insulating layer 140, an interlayer insulating layer 160, a planarization layer 180, a pixel defining layer PDL, a light emitting element 200, an encapsulation layer 230, and a touch layer TCL.

In an embodiment, the transistor TR may include an active pattern 130, a gate electrode 150, a source electrode 170a, and a drain electrode 170b. The light emitting element 200 may include a pixel electrode 190, a light emitting layer 210, and a common electrode 220. The encapsulation layer 230 may include a first inorganic encapsulation layer 231, an organic encapsulation layer 232, and a second inorganic encapsulation layer 233.

The substrate 110 may include a transparent material or an opaque material. The substrate 110 may be made of a transparent resin substrate. Examples of the transparent resin substrate include polyimide substrates or the like. Alternatively, the substrate 110 may include a quartz substrate, a synthetic quartz substrate, a calcium fluoride substrate, an F-doped quartz substrate, a soda-lime glass substrate, a non-alkali glass substrate, or the like. These may be used alone or in combination with each other.

The buffer layer 120 may be disposed on the substrate 110. The buffer layer 120 may prevent diffusion of impurities from the substrate 110 to the active pattern 130. In addition, the buffer layer 120 may control the transfer rate of heat generated in the process of forming the active pattern 130. In an embodiment, for example, the buffer layer 120 may include an inorganic material such as silicon oxide, silicon nitride, or the like. These may be used alone or in combination with each other.

The active pattern 130 may be disposed on the buffer layer 120. The active pattern 130 may include a source region, a drain region, and a channel region located between the source region and the drain region. In an embodiment, for example, the active pattern 130 may include a metal oxide semiconductor, an inorganic semiconductor (e.g., amorphous silicon, poly silicon), or an organic semiconductor.

The metal oxide semiconductor may include a two-component compound (ABX), a ternary compound (ABₓC_{y}), a four-component compound (ABₓC_{y}D_{z}), or the like containing indium (In), zinc (Zn), gallium (Ga), tin (Sn), titanium (Ti), aluminum (Al), hafnium (Hf), zirconium (Zr), magnesium (Mg), or the like. In an embodiment, for example, the metal oxide semiconductor may include zinc oxide (ZnOₓ), gallium oxide (GaOₓ), tin oxide (SnOx), indium oxide (InOₓ), indium gallium oxide (“IGO”), indium zinc oxide (“IZO”), indium tin oxide. (“ITO”), indium zinc tin oxide (“IZTO”), indium gallium zinc oxide (“IGZO”), or the like. These may be used alone or in combination with each other.

The gate insulating layer 140 may be disposed on the buffer layer 120 and the active pattern 130. The gate insulating layer 140 may cover the active pattern 130. In an embodiment, for example, the gate insulating layer 140 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The gate electrode 150 may be disposed on the gate insulating layer 140. The gate electrode 150 may overlap the channel region of the active pattern 130 in a thickness direction of the substrate 110. In an embodiment, for example, the gate electrode 150 may include a metal, an alloy, a conductive metal oxide, a transparent conductive material, or the like. These may be used alone or in combination with each other.

The interlayer insulating layer 160 may be disposed on the gate insulating layer 140 and the gate electrode 150. The interlayer insulating layer 160 may cover the gate electrode 150. In an embodiment, for example, the interlayer insulating layer 160 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The source electrode 170a and the drain electrode 170b may be disposed on the interlayer insulating layer 160. The source electrode 170a may be connected to the source region of the active pattern 130 through a contact hole defined through a first portion of the gate insulating layer 140 and the interlayer insulating layer 160. The drain electrode 170b may be connected to the drain region of the active pattern 130 through a contact hole defined through a second portion of the gate insulating layer 140 and the interlayer insulating layer 160. In an embodiment, for example, each of the source electrode 170a and the drain electrode 170b may include a metal, an alloy, a metal nitride, a conductive metal oxide, a transparent conductive material, or the like. These may be used alone or in combination with each other.

Accordingly, the transistor TR including the active pattern 130, the gate electrode 150, the source electrode 170a, and the drain electrode 170b may be disposed in the display area DA on the substrate 110.

The planarization layer 180 may be disposed on the interlayer insulating layer 160, the source electrode 170a and the drain electrode 170b. The planarization layer 180 may sufficiently cover the source electrode 170a and the drain electrode 170b. The planarization layer 180 may have a substantially flat upper surface. The planarization layer 180 may include an inorganic material and/or an organic material. In an embodiment, for example, the planarization layer 180 may include an organic insulating material such as photoresist, polyacrylic resin, polyimide-based resin, polyamide-based resin, siloxane-based resin, acrylic resin, epoxy-based resin, or the like. These may be used alone or in combination with each other.

The pixel electrode 190 may be disposed on the planarization layer 180. The pixel electrode 190 may be connected to the drain electrode 170b through a contact hole defined through a portion of the planarization layer 180. In an embodiment, for example, the pixel electrode 190 may include a metal, an alloy, a conductive metal oxide, a transparent conductive material, or the like. These may be used alone or in combination with each other. The pixel electrode 190 may be an anode electrode. Alternatively, the pixel electrode 190 may be a cathode electrode.

The pixel defining layer PDL may be disposed on the planarization layer 180. An opening exposing at least a portion of an upper surface of the pixel electrode 190 may be defined in the pixel defining layer PDL. The pixel defining layer PDL may include an organic material and/or an inorganic material. In an embodiment, for example, the pixel defining layer PDL may include an organic material such as photoresist, polyacrylic resin, polyimide resin, polyamide resin, siloxane resin, acrylic resin, epoxy resin, or the like. These may be used alone or in combination with each other.

The light emitting layer 210 may be disposed on the pixel electrode 190. In an embodiment, the light emitting layer 210 may be disposed within the opening of the pixel defining layer PDL. The light emitting layer 210 may include a light emitting material for emitting light. In an embodiment, for example, the light emitting layer 210 may include an organic light emitting material and/or an inorganic light emitting material.

The common electrode 220 may be disposed on the pixel defining layer PDL and the light emitting layer 210. In an embodiment, for example, the common electrode 220 may include a metal, an alloy, a metal nitride, a conductive metal oxide, a transparent conductive material, or the like. These may be used alone or in combination with each other. The common electrode 220 may be a cathode electrode. Alternatively, the common electrode 220 may be an anode electrode.

Accordingly, the light emitting element 200 including the pixel electrode 190, the light emitting layer 210, and the common electrode 220 may be disposed on the substrate 110 in the display area DA. The light emitting element 200 may be electrically connected to the transistor TR.

The encapsulation layer 230 may be disposed on the common electrode 220. The encapsulation layer 230 may prevent impurities, moisture, or the like from permeating the light emitting element 200 from the outside. In an embodiment, as described above, the encapsulation layer 230 may include a first inorganic encapsulation layer 231, an organic encapsulation layer 232, and a second inorganic encapsulation layer 233.

The first inorganic encapsulation layer 231 may be disposed on the common electrode 220. The first inorganic encapsulation layer 231 may include an inorganic material such as silicon oxide, silicon nitride, silicon oxynitride, or the like. These may be used alone or in combination with each other.

The organic encapsulation layer 232 may be disposed on the first inorganic encapsulation layer 231. The organic encapsulation layer 232 may have a sufficient thickness and have a substantially flat upper surface. In an embodiment, for example, the organic encapsulation layer 232 may include a polymer cured material such as polyacrylate, or the like.

The second inorganic encapsulation layer 233 may be disposed on the organic encapsulation layer 232. The first inorganic encapsulation layer 231 and the second inorganic encapsulation layer 233 may have a larger area than the organic encapsulation layer 232. The organic encapsulation layer 232 may not be exposed to the outside by the first inorganic encapsulation layer 231 and the second inorganic encapsulation layer 233. In an embodiment, for example, the second inorganic encapsulation layer 233 may include an inorganic material such as silicon oxide, silicon nitride, silicon oxynitride, or the like. These may be used alone or in combination with each other.

The touch layer TCL may be disposed on the second inorganic encapsulation layer 233. The touch layer TCL may sense a user's touch. In an embodiment, for example, the touch layer TCL may include a first touch insulating layer, a first touch electrode disposed on the first touch insulating layer, a second touch insulating layer covering the first touch electrode, and a second touch electrode disposed on the second touch insulating layer and connected to the first touch electrode, and a protective layer covering the second touch electrode. Each of the first and second touch insulating layers may include an inorganic material, and the protective layer may include an organic material.

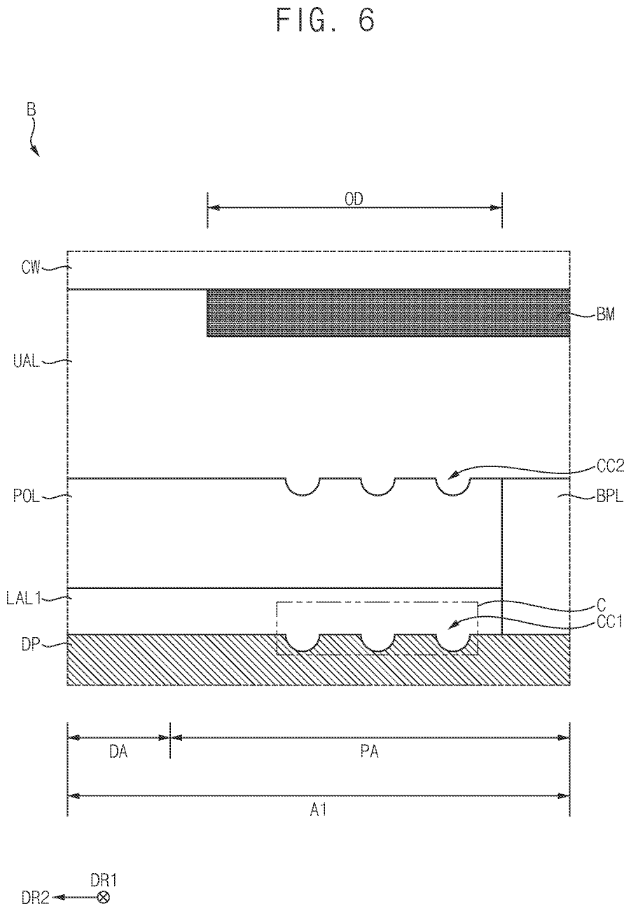

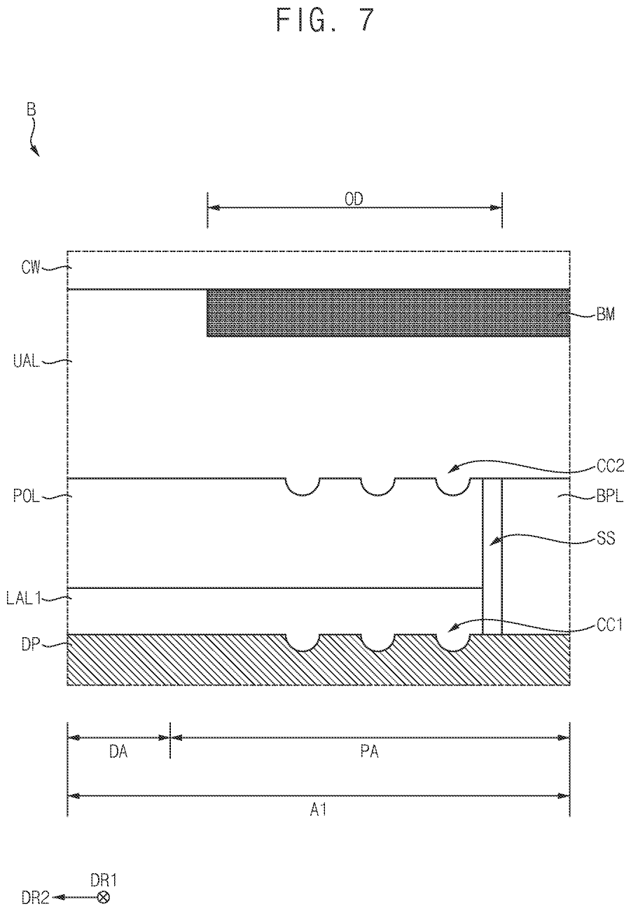

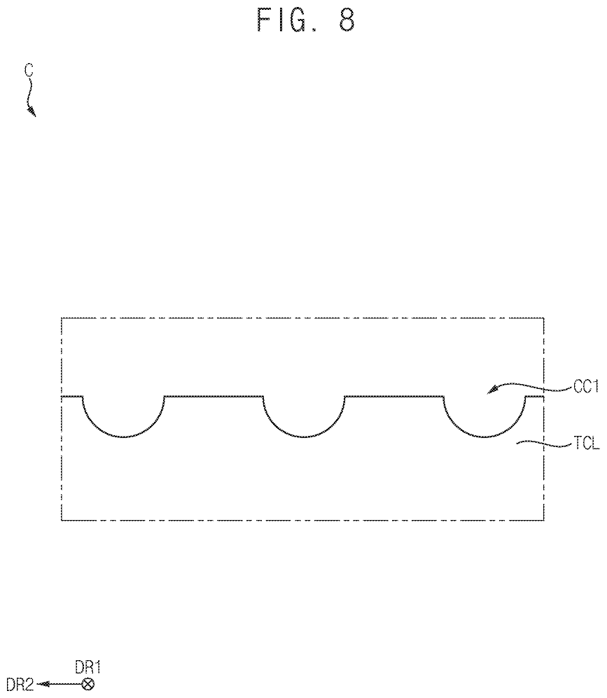

FIG. 6 is an enlarged cross-sectional view of an example of area B of FIG. 3. FIG. 7 is an enlarged cross-sectional view of another example of area B of FIG. 3. FIG. 8 is an enlarged cross-sectional view of area C of FIG. 6.

Referring to FIGS. 6, 7, and 8, in an embodiment, the upper surface of the display panel DP may include a first concave-convex pattern CC1 protruding or depressed (or recessed) in a thickness direction, and the upper surface of the polarizing member POL may have a second concave-convex pattern CC2 protruding or recessed in the thickness direction. Here, the term “a concave-convex pattern” means any uneven surface portion in which a protruded portion and a recessed portion are repeatedly and alternately arranged with each other, without being limited to any specific cross-sectional shape, e.g., a concave shape or a convex shape. Here, the protruded portion means a portion adjacent to the recessed portion and protruded with respect to the recessed portion. Here, the protruded portion may not be protruded with respect to a flat surface portion of the upper surface. In an embodiment, the first concave-convex pattern CC1 may include a first protrusion and a first depression (or recess), and the first protrusion of the first concave-convex pattern CC1 may protrude with respect to the first depression in the thickness direction. In addition, the second concave-convex pattern CC2 may include a second protrusion and a second depression, and the second protrusion of the second concave-convex pattern CC2 may protrude with respect to the second depression in the thickness direction.

Here, the thickness direction may be perpendicular to each of the first and second directions DR1 and DR2. As the upper surface of the display panel DP has the first concave-convex pattern CC1, interfacial adhesion between the display panel DP and the polarization member POL may be enhanced. In addition, as the upper surface of the polarization member POL has the second concave-convex pattern CC2, interface adhesion between the upper adhesive layer UAL and the polarization member POL may be enhanced.

Each of the first concave-convex pattern CC1 and the second concave-convex pattern CC2 may overlap at least a portion of the peripheral area PA in the plan view. In an embodiment, each of the first concave-convex pattern CC1 and the second concave-convex pattern CC2 may overlap a portion of the peripheral area PA adjacent to the bending protection layer BPL in the plan view.

The first lower adhesive layer LAL1 may cover the first concave-convex pattern CC1. In addition, the upper adhesive layer UAL may cover the second concave-convex pattern CC1. That is, the first concave-convex pattern CC1 may directly contact the first lower adhesive layer LAL1 and the second concave-convex pattern CC2 may directly contact the upper adhesive layer UAL.

The second concave-convex pattern CC2 may overlap the first concave-convex pattern CC1 in the plan view. That is, the second concave-convex pattern CC2 may be formed to correspond to the first concave-convex pattern CC1. However, the configuration of the present disclosure is not limited thereto, and the second concave-convex pattern CC2 may partially overlap the first concave-convex pattern CC1 in the plan view. In an embodiment, as illustrated in FIG. 6, the bending protection layer BPL may directly contact the first lower adhesive layer LAL1 and the polarization member POL in the peripheral area PA.

After reliability evaluation is performed on the polarization member POL in a high temperature and high humidity environment, the polarization member POL may shrink due to moisture permeation therein. In this case, as illustrated in FIG. 7, when the polarization member POL is shrunk, the bending protection layer BPL may be spaced apart from the first lower adhesive layer LAL1 and the polarization member POL in the peripheral area PA. In this case, a separation space SS may be formed between the bending protection layer BPL, the polarization member POL, and the first lower adhesive layer LAL1.

A portion of the light blocking layer BM that overlaps the polarization member POL in the plan view may be defined as an overlapping distance OD. However, when the polarization member POL is shrunk as illustrated in FIG. 7, the portion of the light blocking layer BM overlapping the polarizing member POL and the separation space SS in the plan view may be defined as the overlapping distance OD. When the overlapping distance OD is large, the dead space of the display device DD may increase. On the other hand, when the overlapping distance OD is small, the dead space of the display device DD may be reduced. The dead space of the display device DD may refer to areas other than the display area DA (i.e., the peripheral area PA, the bending area BA, and the second area A2 of FIG. 1).

As illustrated in FIG. 7, due to shrinkage of the polarization member POL, the polarization member POL may be separated from the bending protection layer BPL. In this case, the light blocking layer BM may be desired to overlap a portion of the polarization member POL in the plan view to prevent air bubbles generated by the separation space SS between the polarization member POL and the bending protection layer BPL from being visible. In an embodiment, the light blocking layer BM may overlap a portion of the polarization member POL in the plan view. That is, the polarization member POL may not be exposed by the light blocking layer BM. In addition, the light blocking layer BM may at least partially overlap each of the first and second concave-convex patterns CC1 and CC2 in the plan view. In an embodiment, for example, as illustrated in FIGS. 6 and 7, the light blocking layer BM may overlap all of the first and second concave-convex patterns CC1 and CC2 in the plan view.

According to a comparative example, each of the upper surface of the display panel DP and the upper surface of the polarization member POL may not have a concave-convex pattern. In this case, when shrinkage of the polarization member POL occurs, the light blocking layer BM may not overlap the polarization member POL in the plan view. In addition, when the bending protection layer BPL is formed on the display panel DP, a step may occur between the polarization member POL and the bending protection layer BPL. After forming the upper adhesive layer UAL on the polarization member POL and the bending protection layer BPL due to the step, air bubbles may be formed at the end of the upper adhesive layer UAL adjacent to the bending protective layer BPL. In this case, the light blocking layer BM is desired to overlap a region where the air bubbles bubble is formed to prevent the air bubbles from being visible. That is, there is a limit to reducing the dead space of the display device DD due to the shrinkage of the polarization member POL and the formation of the air bubbles due to the step.

In the display device DD according to an embodiment, the upper surface of a display panel DP may have the first concave-convex pattern CC1 protruding or recessed in the thickness direction, and the upper surface of the polarization member POL disposed on the display panel DP may have the second concave-convex pattern CC2 protruding or recessed in the thickness direction. As the upper surface of the display panel DP has the first concave-convex pattern CC1, interfacial adhesion between the display panel DP and the polarization member POL may be enhanced. In addition, as the upper surface of the polarization member POL has the second concave-convex pattern CC2, the interface adhesion between the polarization member POL and the upper adhesive layer UAL may be enhanced.

Accordingly, in such an embodiment, shrinkage due to moisture penetrating into the inside of the polarization member POL may be improved after a reliability evaluation is performed on the polarization member POL in a high-temperature and high-humidity environment. That is, even after shrinkage of the polarization member POL, the light blocking layer BM may overlap a portion of the polarization member POL in the plan view.

In such an embodiment, when the bending protection layer BPL is formed on the display panel DP, a step may not occur between the polarization member POL and the bending protection layer BPL, and air bubbles may not be generated due to the step at an end of the upper adhesive layer UAL adjacent to the bending protection layer BPL.

As a result, the overlapping distance OD may be reduced compared to the comparative example. Accordingly, in an embodiment of the invention, the dead space of the display device DD may be reduced.

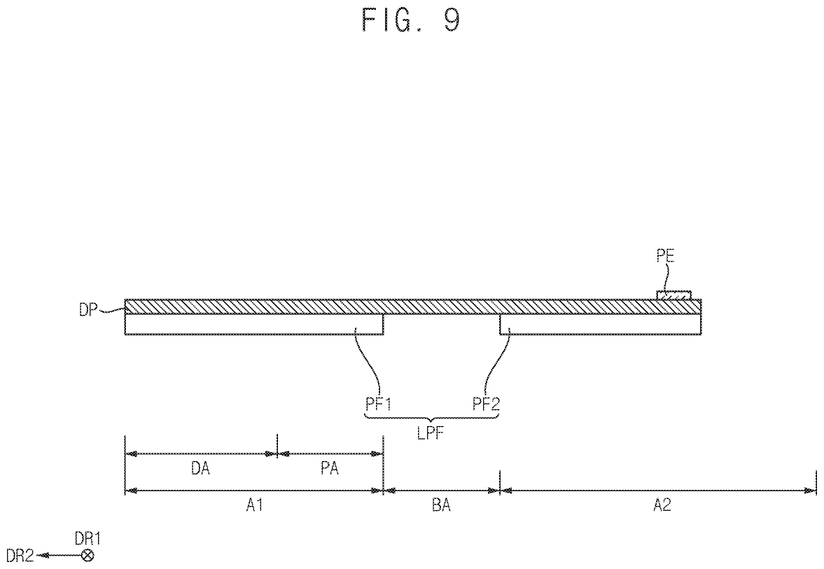

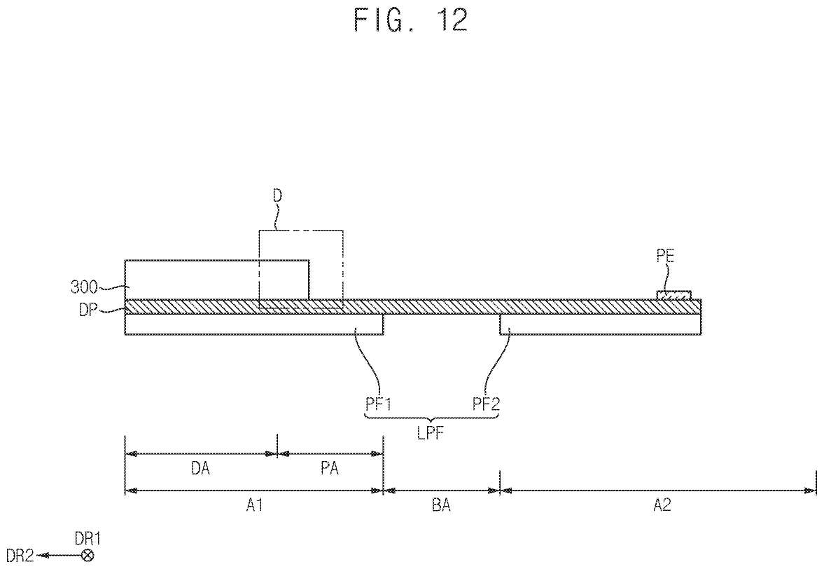

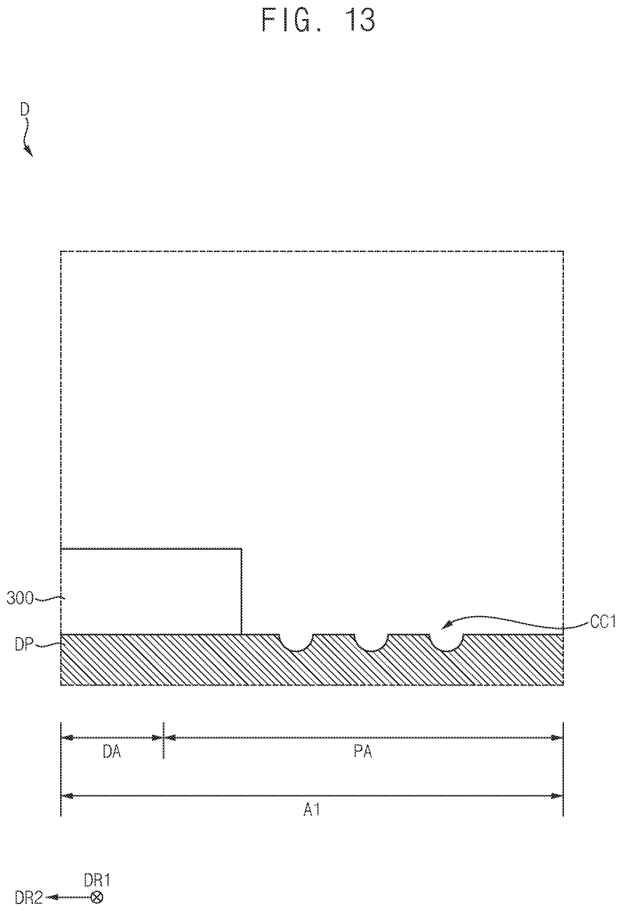

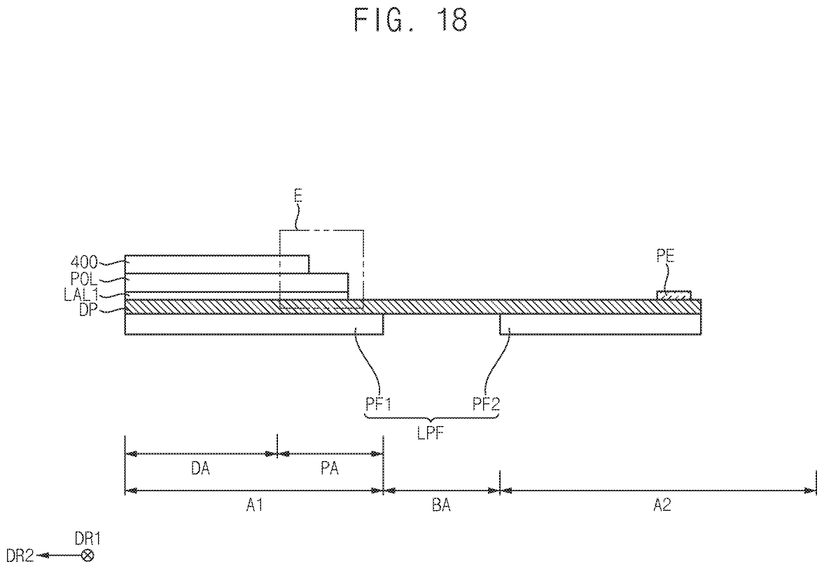

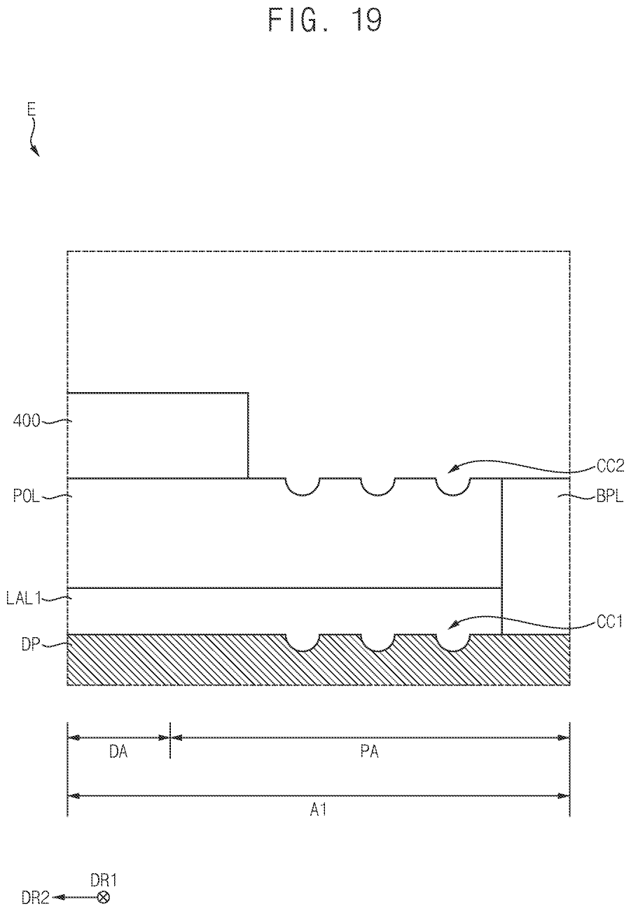

FIGS. 9 to 23 are cross-sectional views showing processes of an embodiment of a method for manufacturing the display device of FIGS. 3 to 8.

Referring to FIG. 9, the display panel DP including the first area A1, the bending area BA, and the second area A2 may be provided or prepared. The pad electrode PE may be formed in the second area A2 on the display panel DP.

The lower protective film LPF may be formed on the lower surface of the display panel DP. In an embodiment, the first protective film PF1 may be formed in the first area A1 on the lower surface of the display panel DP, and the second protective film PF2 in the second area A2 on the lower surface of the display panel DP may be formed. In such an embodiment, the first protective film PF1 and the second protective film PF2 may not overlap the bending area BA. In an embodiment, for example, the lower protective film LPF may be formed using an inorganic material and/or an organic material.

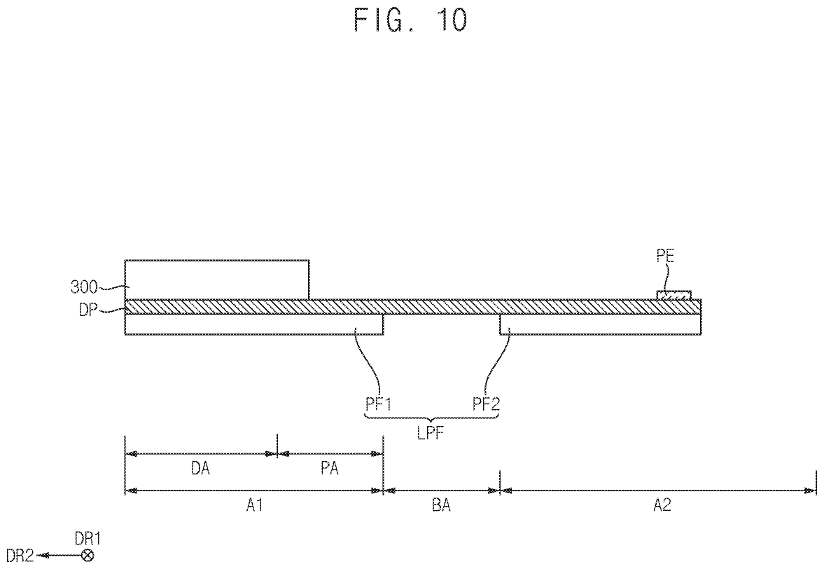

Referring to FIG. 10, a panel protection film 300 may be formed in the first area A1 on the display panel DP. The display panel DP may be provided with the panel protection film 300 formed thereon. The panel protection film 300 may protect the display panel DP. In an embodiment, for example, the panel protection film 300 may be formed using an inorganic material and/or an organic material.

In an embodiment, the panel protection film 300 having a size determined to overlap the display area DA and a portion of the peripheral area PA may be formed on the display panel DP. That is, before the panel protection film 300 is formed on the display panel DP, the panel protection film 300 may have a size determined to overlap the display area DA and a portion of the peripheral area PA.

In an alternative embodiment, after the panel protection film 300 is entirely formed on the display panel DP, the panel protection film 300 may be cut by a laser beam. Accordingly, the panel protection film 300 may be formed overlapping the display area DA and a portion of the peripheral area PA.

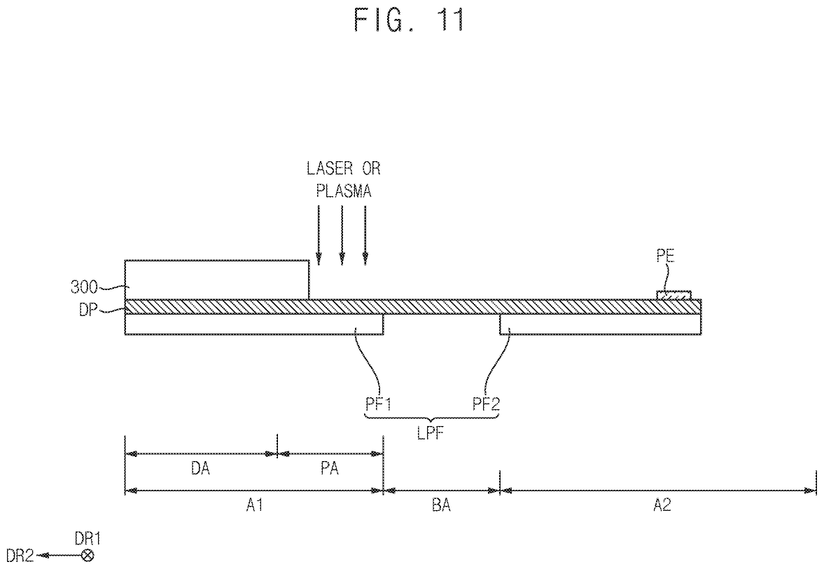

Referring to FIGS. 11, 12, and 13, in an embodiment, a laser beam may be radiated to an upper surface of the display panel DP that does not overlap (or is not covered by) the panel protection film 300. In an alternative embodiment, plasma is applied to an upper surface of the display panel DP that does not overlap the panel protection film 300.

As the upper surface of the display panel DP is irradiated with the laser beam or treated with plasma, the first concave-convex pattern CC1 protruding or recessed in the thickness direction may be formed on the upper surface of the display panel DP, e.g., by forming concave recesses on the display panel DP. The first concave-convex pattern CC1 may overlap a portion of the peripheral area PA in the plan view.

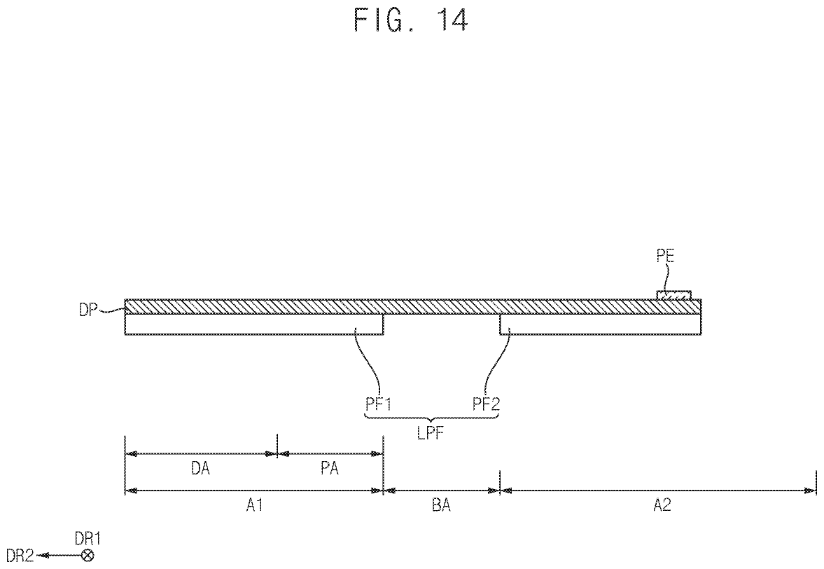

Referring to FIG. 14, after the first concave-convex pattern CC1 is formed on the upper surface of the display panel DP, the panel protection film 300 may be removed.

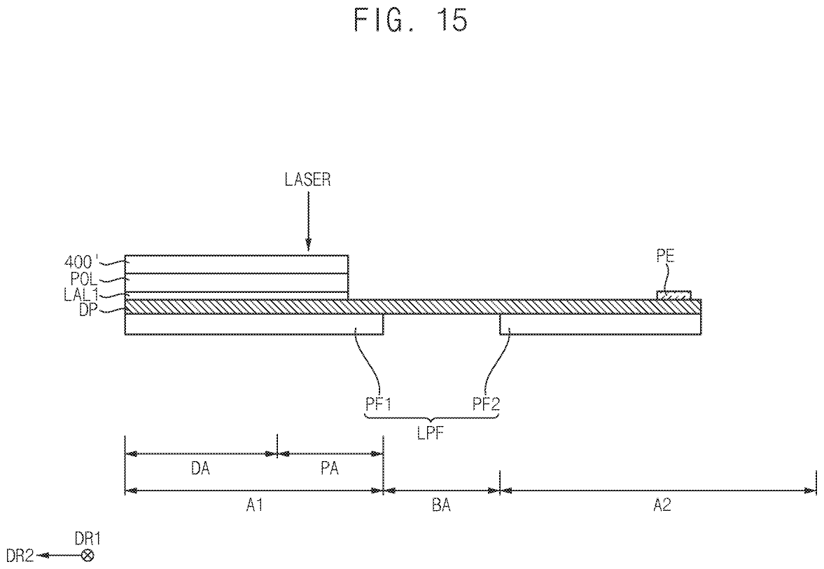

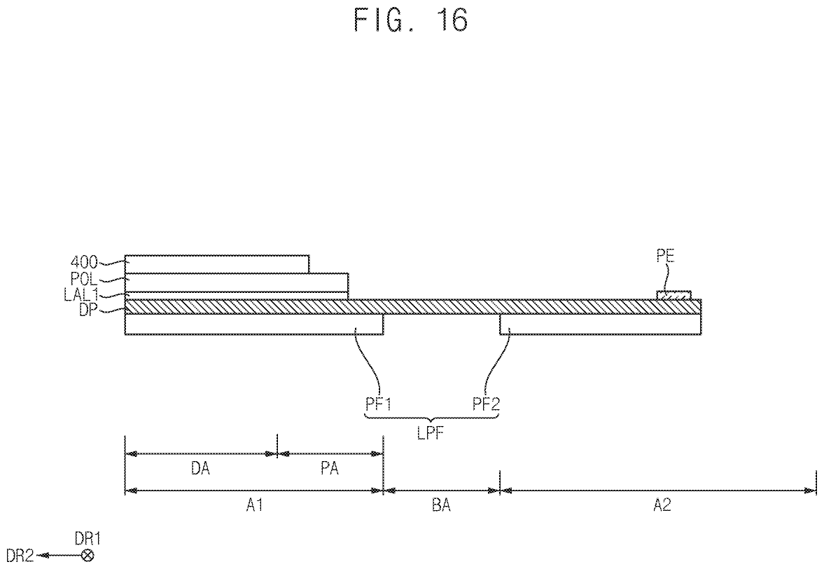

Referring to FIGS. 15 and 16, the first lower adhesive layer LAL1 may be formed on the display panel DP. The first lower adhesive layer LAL1 may be formed to overlap the display area DA and a portion of the peripheral area PA. In an embodiment, for example, the first lower adhesive layer LAL1 may be formed using OCA, PSA, OCR, or the like.

A polarization protection film 400 may be formed on the polarization member POL. In an embodiment, after the polarization protection film 400 is formed on the polarization member POL, the polarization member POL, on which the polarization protection film 400 is formed, may be attached to the display panel DP through the first lower adhesive layer LAL1. The polarization protection film 400 may protect the polarization member POL. In an embodiment, for example, the polarization protection film 400 may be formed using an inorganic material and/or an organic material.

In an embodiment, after a preliminary polarization protection film 400′ is entirely formed on the polarization member POL, the polarization member POL, on which the preliminary polarization protection film 400′ is formed, may be attached to the display panel DP. Then, the preliminary polarization protection film 400′ may be cut through a laser beam. Accordingly, the polarization protection film 400 may be formed to overlap the display area DA and the portion of the peripheral area PA.

In an alternative embodiment, the polarization protection film 400 having a size determined to overlap the display area DA and the portion of the peripheral area PA may be formed on the polarization member POL. Then, the polarization member POL on which the polarization protection film 400 is formed may be attached to the display panel DP.

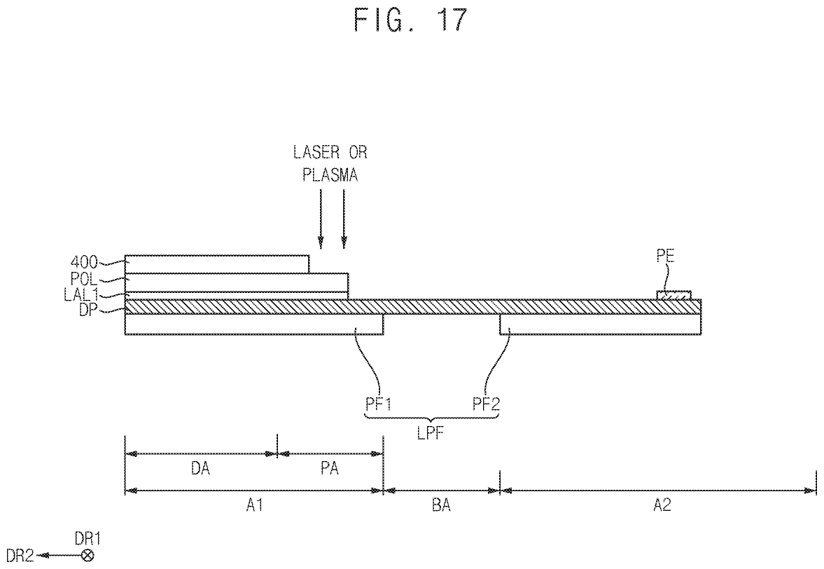

Referring to FIGS. 17, 18, and 19, in an embodiment, the laser beam may be radiated to an upper surface of the polarization member POL that does not overlap with the polarization protection film 400. In an alternative embodiment, the plasma is applied to the upper surface of the polarization member POL that does not overlap with the polarization protection film 400.

As the upper surface of the polarization member POL that does not overlap the polarization protection film 400 is irradiated with the laser beam or treated with the plasma, the second concave-convex pattern CC2 protruding in the thickness direction from the upper surface of the polarizing member POL may be formed, e.g., by forming concave recesses on the polarization member POL. The second concave-convex pattern CC2 may overlap a portion of the peripheral area PA. In addition, the second concave-convex pattern CC2 may at least partially overlap the first concave-convex pattern CC1 in the plan view.

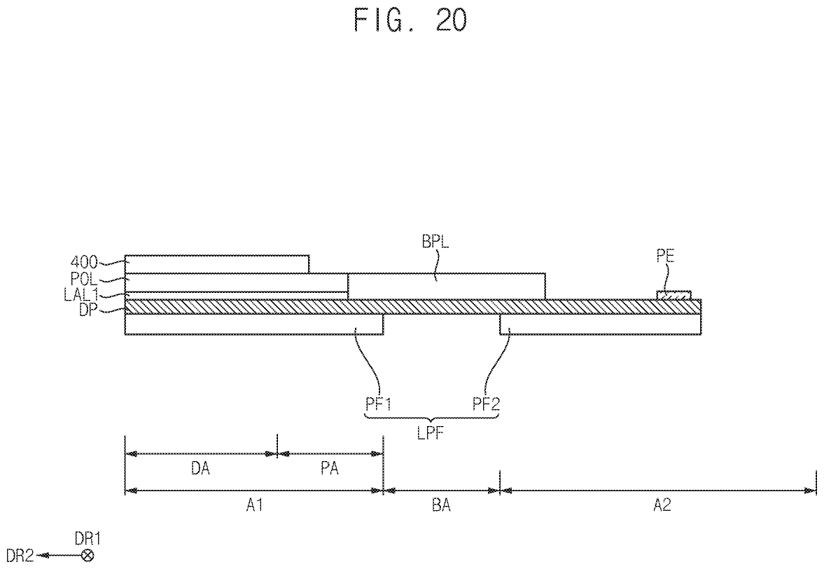

Referring to FIG. 20, the bending protection layer BPL may be formed on the display panel DP. In an embodiment, the bending protection layer BPL may be formed by applying a material for the bending protection layer BPL on the display panel DP and then curing the material with ultraviolet rays. The bending protection layer BPL may be formed to overlap a portion of the peripheral area PA, the bending area BA, and a portion of the second area A2. In an embodiment, for example, the bending protection layer BPL may be formed to directly contact the first lower adhesive layer LAL1 and the polarization member POL in the peripheral area PA. The bending protection layer BPL may be formed using a photocurable resin and/or a thermosetting resin.

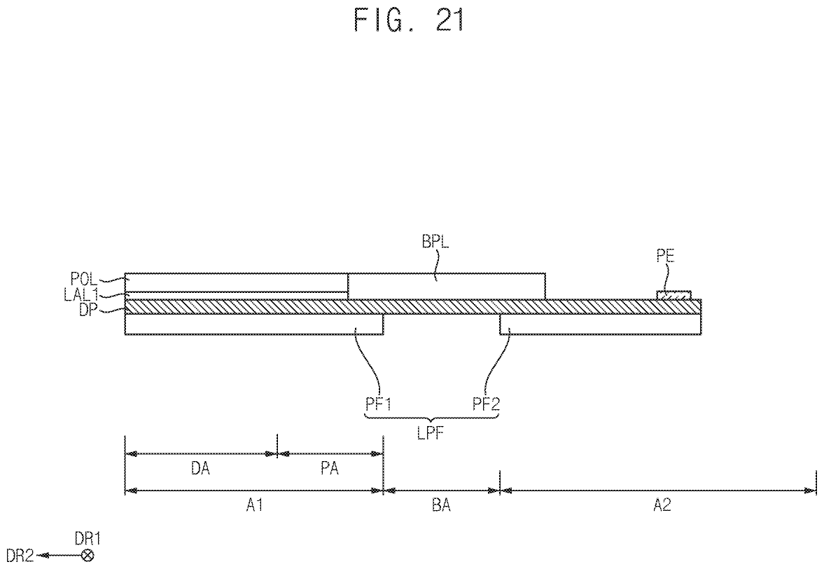

Referring to FIG. 21, after the bending protection layer BPL is formed on the display panel DP, the polarization protection film 400 may be removed.

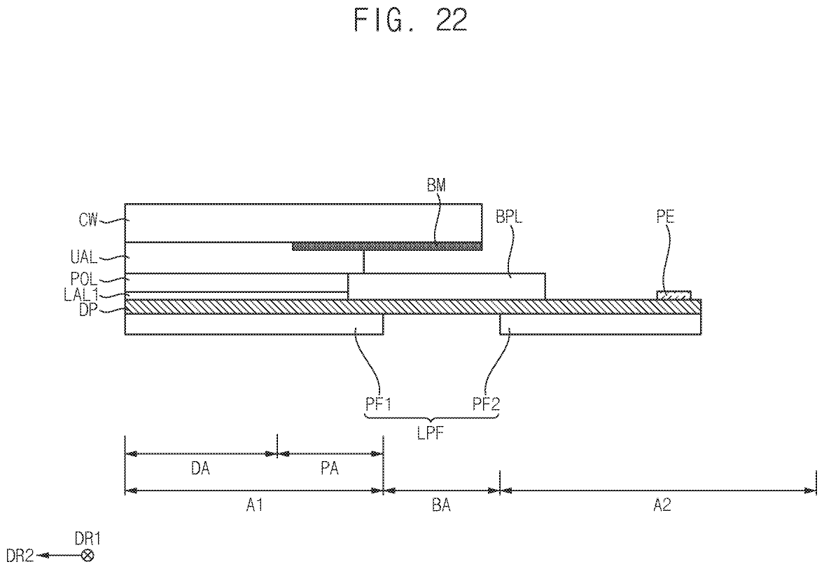

Referring to FIG. 22, the upper adhesive layer UAL may be formed on the polarization member POL. The upper adhesive layer UAL may be formed to overlap a portion of the bending protection layer BPL and the polarization member POL. In an embodiment, for example, the upper adhesive layer UAL may be formed using OCA, PSA, OCR, or the like.

The light blocking layer BM may be formed on the lower surface of the cover window CW. In an embodiment, the light blocking layer BM may directly contact the lower surface of the cover window CW. The light blocking layer BM may be formed to overlap a portion of the peripheral area PA and the bending area BA. In an embodiment, for example, the light blocking layer BM may be formed using an inorganic material and/or an organic material containing a light blocking material.

After the light blocking layer BM is formed on the lower surface of the cover window CW, the cover window CW and the light blocking layer BM may be attached to the polarization member POL and the bending protection layer BPL through the upper adhesive layer UAL. After the cover window CW and the light blocking layer BM are attached to the polarization member POL and the bending protection layer BPL, air bubbles may be formed between the polarization member POL and the upper adhesive layer UAL. In an embodiment, a process of removing the air bubbles may be performed to prevent the air bubbles from being visible. In an embodiment, the air bubbles may be removed through an autoclave. The autoclave is a process of removing the air bubbles by applying heat and pressure.

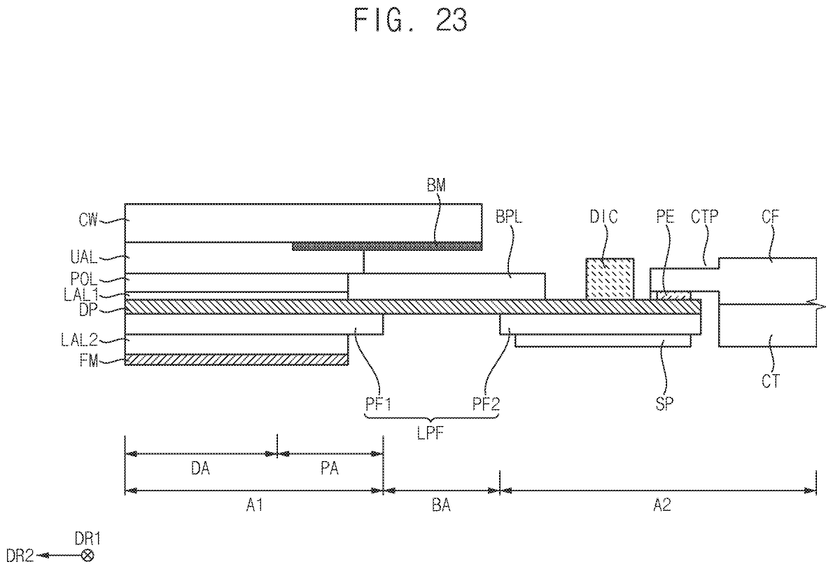

Referring to FIG. 23, the driving integrated circuit DIC may be provided or formed in the second area A2 on the display panel DP. In an embodiment, for example, the driving integrated circuit DIC may be a data driver.

The connection film CF may be formed in the second area A2 on the display panel DP. In an embodiment, one end of the connection film CF may be attached to the pad electrode PE. The conductive tape CT may be formed on the lower surface of the connection film CF. In an embodiment, for example, the conductive tape CT may be formed using an anisotropic conductive film or the like.

The spacer SP may be formed on the lower surface of the second protective film PF2. In an embodiment, for example, the spacer SP may be formed using an organic insulating material.

The functional member FM may be formed on the lower surface of the first protection film PF1. The functional member FM may be attached to the lower surface of the first protection film PF1 through the second lower adhesive layer LAL2. In an embodiment, for example, the second lower adhesive layer LAL2 may be formed using OCA, PSA, OCR, or the like. In an embodiment, for example, the functional member FM may include a digitizer, a heat dissipation plate, or the like.

Referring back to FIGS. 3 and 4, a portion of the display panel DP overlapping the bending area BA may be bent. In an embodiment, the portion of the display panel DP overlapping the bending area BA may be bent in a way such that the spacer SP contacts the functional member FM and the conductive tape CT contacts the functional member FM.

After the portion of the display panel DP overlapping the bending area BA is bent, the cover tape CTP may be formed in the second area A2 on the driving integrated circuit DIC. The cover tape CTP may be formed on a portion of the bending protection layer BPL and a portion of the connection film CF. That is, the cover tape CTP may cover the driving integrated circuit DIC. In an embodiment, for example, the cover tape CTP may include a synthetic resin such as PET or the like. Alternatively, the cover tape CTP may be formed before the display panel DP is bent.

Accordingly, the display device DD shown in FIGS. 3 and 4 may be manufactured.

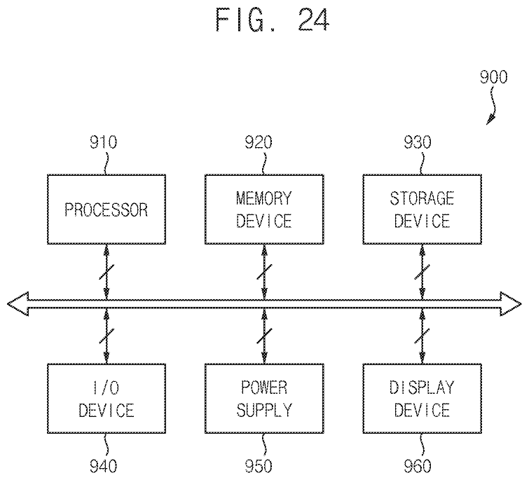

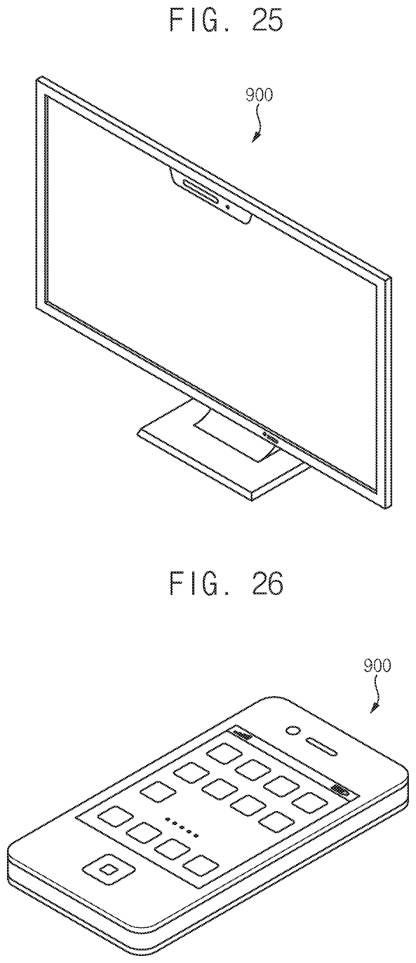

FIG. 24 is a block diagram illustrating an embodiment of an electronic device including the display device of FIG. 1. FIG. 25 is a view illustrating an embodiment in which the electronic device of FIG. 24 is implemented as a television. FIG. 26 is a view illustrating an embodiment in which the electronic device of FIG. 24 is implemented as a smart phone.

Referring to FIGS. 24, 25 and 26, in an embodiment, the electronic device 900 may include a processor 910, a memory device 920, a storage device 930, an input/output (“I/O”) device 940, a power supply 950 and a display device 960. In such an embodiment, the display device 960 may correspond to the display device DD described with reference to FIGS. 1 to 8. The electronic device 900 may further include various ports capable of communicating with a video card, a sound card, a memory card, a USB device, or the like.

In an embodiment, as illustrated in FIG. 25, the electronic device 900 may be implemented as a television. In an alternative embodiment, as illustrated in FIG. 26, the electronic device 900 may be implemented as a smart phone. However, embodiments are not limited thereto, in another alternative embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. The processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

The storage device 930 may include a solid state drive (“SSD”) device, a hard disk drive (“HDD”) device, a CD-ROM device, or the like.

The I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be coupled to other components via the buses or other communication links. In an embodiment, the display device 960 may be included in the I/O device 940.

Embodiments of the display device DD according to the present disclosure can be applied to various electronic devices. For example, the present disclosure is applicable to various display devices such as display devices for vehicles, ships and aircraft, portable communication devices, display devices for exhibition or information transmission, medical display devices, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a display area and a peripheral area adjacent to the display area, and including an upper surface having a first concave-convex pattern protruding or recessed in a thickness direction;
a polarization member disposed on the display panel, overlapping the display area and a portion of the peripheral area, and including an upper surface having a second concave-convex pattern protruding or recessed in the thickness direction;
a cover window disposed on the polarization member; and
a light blocking layer disposed on a lower surface of the cover window and overlapping a portion of the peripheral area.

2. The display device of claim 1, wherein each of the first concave-convex pattern and the second concave-convex pattern overlaps the portion of the peripheral area.

3. The display device of claim 1, wherein the light blocking layer overlaps a portion of the polarization member.

4. The display device of claim 1, wherein the light blocking layer overlaps each of the first concave-convex pattern and the second concave-convex pattern in the thickness direction.

5. The display device of claim 1, wherein the display panel includes:
a transistor disposed in the display area on a substrate;
a light emitting element disposed on the transistor and electrically connected to the transistor;
an encapsulation layer disposed on the light emitting element; and
a touch layer disposed on the encapsulation layer.

6. The display device of claim 5, wherein an upper surface of the touch layer defines the first concave-convex pattern.

7. The display device of claim 1, wherein the display panel further includes a pad area and a bending area located between the peripheral area and the pad area in a plan view.

8. The display device of claim 7, further comprising:
a bending protection layer disposed on the display panel and overlapping a portion of the peripheral area and the bending area.

9. The display device of claim 8, wherein each of the first concave-convex pattern and the second concave-convex pattern overlaps a portion of the peripheral area adjacent to the bending protection layer.

10. The display device of claim 8, wherein the bending protection layer directly contacts the polarization member in the peripheral area.

11. The display device of claim 8, wherein the bending protection layer is spaced apart from the polarization member in the peripheral area.

12. A method for manufacturing a display device, the method comprising:
preparing a display panel including a display area and a peripheral area adjacent to the display area;
forming a first concave-convex pattern protruding or recessed in a thickness direction on an upper surface of the display panel;
attaching a polarization member to the display panel to overlap the display area and a portion of the peripheral area;
forming a second concave-convex pattern protruding or recessed in the thickness direction on an upper surface of the polarization member;
providing a light blocking layer on a lower surface of a cover window; and
attaching the cover window and the light blocking layer to the polarization member in a way such that the light blocking layer overlaps a portion of the peripheral area.

13. The method of claim 12, further comprising:
providing a panel protection film on the display panel before the forming the first concave-convex pattern,
wherein the attaching the polarization member to the display panel includes:
providing a polarization protection film on the polarization member; and
attaching the polarization member, on which the polarization protection film is provided, to the display panel.

14. The method of claim 13, further comprising:
removing the panel protection film after the forming the first concave-convex pattern.

15. The method of claim 13, further comprising:
removing the polarization protection film after the forming the second concave-convex pattern.

16. The method of claim 13, wherein the forming the first concave-convex pattern comprises radiating a laser beam or applying plasma to a portion of an upper surface of the display panel which does not overlap the panel protection film and overlaps a portion of the peripheral area.

17. The method of claim 13, wherein the forming the second concave-convex pattern comprises radiating a laser beam or applying plasma to a portion of an upper surface of the polarization member which does not overlap the polarization protection film and overlaps a portion of the peripheral area.

18. The method of claim 12, wherein the attaching the polarization member to the display panel includes:
providing a preliminary polarization protection film entirely on the polarization member;
attaching the polarization member, on which the preliminary polarization protection film is provided, to the display panel; and
forming a polarization protection film overlapping the display area and a portion of the peripheral area by cutting the preliminary polarization protection film using a laser beam.

19. The method of claim 12, wherein the attaching the polarization member on the display panel includes:
providing a polarization protection film having a size determined to overlap the display area and a portion of the peripheral area on the polarization member; and
attaching the polarization member, on which the polarization protection film is provided, to the display panel.

20. The method of claim 12, further comprising:
removing air bubbles formed between the polarization member and the cover window after the attaching the cover window and the light blocking layer to the polarization member,
wherein the air bubbles are removed by an auto clave.
